(19) United States
(12) Patent Application Publication
(10) Pub. No.: US 2008/0150421 A1
(43) Pub. Date: Jun. 26, 2008

(54) ORGANIC LIGHT-EMITTING APPARATUS

(75) Inventor: Kenji Takata, Kawasaki-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 11/960,039

(22) Filed: Dec. 19, 2007

(30) Foreign Application Priority Data
Dec. 21, 2006 (JP) 2006-343772
Nov. 21, 2007 (JP) 2007-301429

(51) Int. Cl. H01J 1/62

(52) U.S. Cl. 313/504

(57) ABSTRACT

An organic light-emitting apparatus is provided which is reduced in reflection of light incident on an organic light-emitting device and has a high contrast in a light environment. The organic light-emitting apparatus has a number of organic light-emitting devices and has contact holes formed for providing electrical connection to the organic light-emitting devices having a polarizing plate on a light extraction surface side. The organic light-emitting apparatus further has, on the contact holes, an insulating layer which is a light transmissive member, has an opening defining a light-emitting region of the organic light-emitting device, and covers an opening of a planarizing layer and a region between adjacent portions of a first electrodes, and a light shielding layer formed on the insulating layer so as to cover the opening in the planarizing layer.

### BACKGROUND OF THE INVENTION

2. Field of the Invention

The present invention relates to an organic light-emitting apparatus provided with an organic electroluminescence (hereinafter, simply referred to as “EL”) device.

2. Description of the Related Art

An organic light-emitting apparatus with a plurality of organic EL devices as organic light-emitting devices designed for being driven by an active matrix circuit has a configuration, for instance, such as illustrated in FIGS. 3 and 4.

On a glass substrate 500, a thin-film transistor (TFT) 501 is formed which drives an organic light-emitting device (pixel). The TFT 501 has a source region 510, poly-Si 511, a drain region 512, a gate insulating film 513, a gate electrode 514, an interlayer insulating film 515 and a drain electrode 516.

On the TFT 501, an inorganic insulating film 517 is formed, and an organic planarizing film 518 is further formed thereon so as to level the surface of the inorganic insulating film 517.

On the organic planarizing film 518, a (lower) reflective electrode 520, which becomes an anode, is formed. The reflective electrode 520 is patterned for each pixel, and the reflective electrodes 520 and the drain electrodes 516 of the TFT 501are electrically connected to each other through a contact hole 542 which is formed through the inorganic insulating film 517 and the organic planarizing film 518.

A pixel separation film 530 is formed between adjacent pixels so as to cover a periphery of the reflective electrode 520.

On the reflective electrode 520 which is exposed through an opening of the pixel separation film 530, a hole-transporting layer 523, a light-emitting layer 522 and an electron-transporting layer 524 are formed as organic functional layers 525, and an (upper) transparent electrode 521, which becomes a cathode, is further formed thereon.

A sealing glass substrate 540 is bonded onto the substrate 500 by using an ultraviolet curing epoxy resin so as to protect the organic light-emitting device from moisture. An inert gas 541 is filled in between the transparent electrode 521 and the sealing glass substrate 540.

In the organic light-emitting apparatus having the above described configuration, the reflective electrode 520 has a high reflectance for visible light, and reflects a part of light incident from the outside and emits the light from a light-extraction surface.

Accordingly, the organic light-emitting apparatus has low contrast and poor visibility in an environment in which light easily enters the organic light-emitting apparatus, for instance, under sunlight.

For this reason, a contrivance has been recently proposed in which a linearly polarizing plate and a phase difference film are disposed on the light extraction surface side so that exit of light reflected in the organic light-emitting apparatus of lights incident from the outside is reduced (see Japanese Patent Application Laid-Open Nos. H07-142170, H09-127885, and 2005-346043).

The principle of the disclosed technology for reducing the reflected light will now be described with reference to FIG. 5 which illustrates an example of a configuration employing the technology in an organic light-emitting apparatus.

The organic light-emitting apparatus illustrated in FIG. 5 has a reflective layer 14, a light-emitting layer 13, a phase difference compensation film 12 and a polarizing layer 11 stacked. In FIG. 5, the reflective layer 14 and the light-emitting layer 13 are illustrated as if the layers had a space between them for convenience of description, but practically, the light-emitting layer 13 is stacked on the reflective layer 14 in a close contact manner or through another organic layer.

The polarizing layer 11 has a structure for passing only one of p-wave and s-wave of incident light therethrough. The phase difference compensation film 12 has a structure having a plurality of phase difference films (not illustrated) stacked, and has a phase difference of ¼ wavelength in a wide wavelength range. The combination of the polarizing layer 11 and the phase difference compensation film 12 is referred to as a circularly polarizing plate (circularly polarizing member).

Specifically, light which has passed through the polarizing layer 11 and the phase difference compensation film 12 is converted into circularly polarized light, because the p-wave and the s-wave are shifted in phase by ¼ wavelength, in the wide wavelength range.

Light 16 emitted from the light-emitting layer 13 toward the polarizing layer 11 passes through the polarizing layer 11, and exits to the outside of the organic light-emitting apparatus.

On the other hand, light 19 emitted from the light-emitting layer 13 toward the reflective layer 14 is reflected by the reflective layer 14. Then, the reflected light 15 passes through the light-emitting layer 13, the phase difference compensation film 12 and the polarizing layer 11, and exits to the outside of the organic light-emitting apparatus.

Any of the light 16 and the light 19, which have been emitted from the light-emitting layer 13 in such a manner, can exit to the outside of he organic light-emitting apparatus. However, when the light 16 and the light 19 (15) pass through the polarizing layer 11, only one of linear polarization components passes, so that the optical intensity is attenuated.

A part of light 17 incident from the outside of the organic light-emitting apparatus is reflected by the surface of the polarizing layer 11 to become reflected light O. Of the light 17, light which has not been reflected by the polarizing layer 11 is converted into circularly polarized light by the polarizing layer 11 and the phase difference compensation film 12, and is reflected by the reflective layer 14.

When the light 17 is reflected by the reflective layer 14, the light is shifted in phase by a half wavelength, so that light 18 which subsequently has passed through the phase difference compensation film 12 cannot pass through the polarizing layer 11.

By the above described principle, the reflection of ambient light by the organic light-emitting apparatus is limited to only the light O reflected by the surface of the polarizing layer 11 and can be reduced.

Furthermore, Japanese Patent Application Laid-Open No. 2005-346043 describes that an organic light-emitting apparatus can absorb stray light emitted from a light-emitting device by using a material absorbing visible light such as a black pigment or dye, as the pixel separation film, in addition to such a circularly polarized light member, thereby improving the contrast (see paragraph number [0273]).

However, reflection by a highly reflective film such as a metal in an organic light-emitting apparatus can occur not only in a light-emitting region, but also at the outside of the light-emitting region, for instance, in a region of opening (contact hole) which is formed in a planarizing layer.

For light which enters an organic light-emitting apparatus and is reflected an odd number of times in the organic light-emitting apparatus to arrive at a circularly polarizing plate, when the light passes through a transparent electrode or an organic functional layer of a light-emitting region and is reflected once by a reflective electrode (FIG. 6), the conventional configuration is effective. However, of lights which pass through the transparent electrode or the organic functional layer outside the light-emitting region and are reflected by a tapered portion formed in the opening of a planarizing layer or which are scattered by a surface roughness between a TFT or its lead-out line and the reflective electrode at the opening, there is a light which is reflected an even number of times and arrives at the circularly polarizing plate as illustrated in FIG. 7, for instance. The shift in phase of the light reflected an even number of times is not a half wavelength, so that the light passes through the circularly polarizing plate and exits to the outside.

The light which thus passes through the polarizing plate and exits outward reduces the contrast of the organic light-emitting apparatus.

On the other hand, a display apparatus disclosed in Japanese Patent Application Laid-Open No. 2005-346043 has an insulator (pixel separation film) 1214 using a material which absorbs visible light such as a black pigment or dye formed on an opening (contact hole) of an interlayer insulating film 1220, thereby reducing exit to the outside of a panel of light reflected an even number of times of lights reflected at the opening.

When actually forming such a pixel separation film using a material which absorbs visible light in a display apparatus, the film is formed of a photosensitive resin by means of photolithography. In the photolithography, a black matrix is formed by such a design to make an exposed portion insoluble.

However, in the photosensitive resin, a considerable amount of a black coloring agent needs to be used in order to sufficiently enhance the light shielding effect of the black matrix. Then, a radioactive ray for the exposure is absorbed by the coloring agent, so that there is necessarily occurred a phenomenon in which the effective intensity of the radioactive ray in the coating decreases gradually from the surface to the bottom (specifically the vicinity of the surface of the substrate) of the coating. Accordingly, the curing reaction in the coating also tends to gradually become insufficient from the surface to the bottom of the coating. As a result, there has been a problem that the shape of a formed pattern tends to become an inverse tapered shape, or that peeling, falling or chipping occurs in the pattern formed after a developing step, because the adhesion of the coating to the substrate is reduced. Besides, the black photosensitive resin also poses a problem that a residue tends to remain on the substrate of an unexposed portion.

When the pixel separation film is thus formed into an inverse tapered shape, or a residue remains on a lower electrode, stepped cut is produced at a tail of the inverse tapered portion or at a residue remaining portion in an organic compound layer of an organic light-emitting device to cause short-circuiting between the upper electrode and the lower electrode. As a result, a number of pixels are formed in which the organic light-emitting device emits no light.

### SUMMARY OF THE INVENTION

Therefore, the present invention provides an organic light-emitting apparatus showing a high degree of contrast in a light environment by reducing reflected light entering the organic light-emitting device while inhibiting the malfunction of pixel or a region around the pixel, which may occur in the conventional apparatus configuration.

The organic light-emitting apparatus according to the present invention provided for solving the above described problems of the background art includes: a substrate; a plurality of thin-film transistors formed on the substrate; a planarizing layer formed on the plurality of thin-film transistors; a plurality of organic light-emitting devices formed on the planarizing layer, each of which has formed sequentially, on the planarizing layer, a first electrode which is patterned for the organic light-emitting device concerned and is electrically connected to the thin-film transistor through an opening formed in the planarizing layer; an organic compound layer; and a second electrode which is a light transmissive electrode; an insulating layer which is a light transmissive member, covers the opening in the planarizing layer and a region between the adjacent first electrodes, and has an opening defining a light-emitting portion of the organic light-emitting device; a light shielding layer which is formed on the insulating layer and covers the opening in the planarizing layer; and a circularly polarizing member which is disposed on the plurality of organic light-emitting devices and the light shielding layer.

According to the organic light-emitting apparatus of the present invention, because ambient light is absorbed, not by an insulating layer, but by a light shielding layer formed thereon, the problem of generation of disadvantages which occurred in a pixel or a periphery thereof of the conventional apparatus configuration.

Further, of lights incident on the organic light-emitting apparatus from the outside, a light incident on a contact hole region enters a light shielding layer formed above an insulating layer covering the contact hole. When the light shielding layer is a light absorbing member, the ambient light is absorbed as such thereby, so that ambient light which exits to the outside can be remarkably reduced. Furthermore, even when the light shielding layer is a light reflection member, ambient light reflected by the light shielding layer can be reduced in transmission by a polarizing member.

Accordingly, there can be provided an organic light-emitting apparatus which can suppress exit of ambient light and has a high contrast in a light environment.

Further features of the present invention will become apparent from the following description of exemplary embodiments with reference to the attached drawings.

### BRIEF DESCRIPTION OF THE DRAWINGS

FIG. 1 is a schematic cross-sectional view illustrating an organic light-emitting apparatus according to a first embodiment of the present invention.

FIG. 2A is a schematic plan view illustrating a positional relationship of a light shielding layer, and FIG. 2B is a schematic cross-sectional view illustrating a positional relationship of a light shielding layer.

FIG. 3 is a schematic cross-sectional view illustrating a conventional organic light-emitting apparatus which is driven by an active matrix circuit.

FIG. 4 is a schematic cross-sectional view illustrating an organic compound layer.

FIG. 5 is a diagram illustrating a principle of reducing reflection of light by using a polarizing member.

FIG. 6 is a schematic cross-sectional view illustrating a state in which incident light is reflected an odd number of times.

FIG. 7 is a schematic cross-sectional view illustrating a state in which incident light is reflected an even number of times.

FIG. 8 is a schematic cross-sectional view illustrating a state in which when a light shielding layer having a light reflection property is disposed on a tapered portion of an insulating layer, incident light is reflected an even number of times.

### DESCRIPTION OF THE EMBODIMENTS

Embodiments for carrying out the present invention will now be described below with reference to the drawings, but the present invention is not limited to the present embodiment.

Incidentally, the expression “formed on” as herein employed is intended to include not only a case where an upper member (including transistor, layer, device, electrode, and the like) is formed in contact with a lower member (including substrate, transistor, layer, electrode, device, and the like) but also a case where the upper member is formed through another member (layer or the like) above the lower member.

### First Embodiment

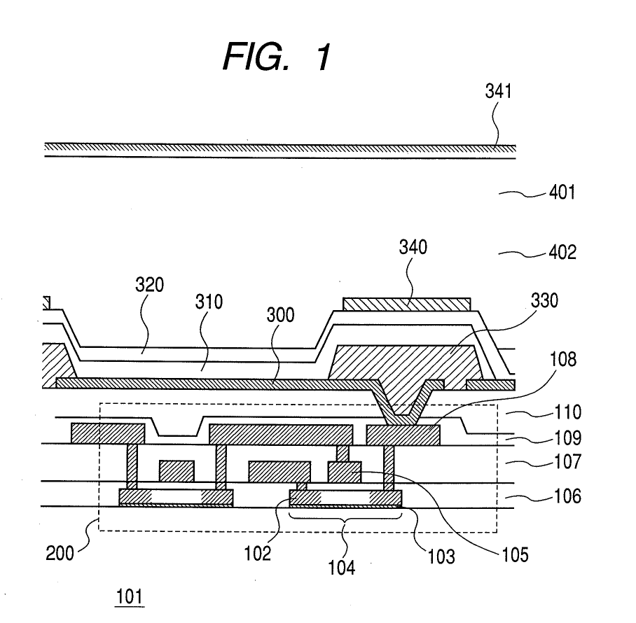

FIG. 1 is a schematic view illustrating an organic light-emitting apparatus according to the present embodiment.

The organic light-emitting apparatus has a configuration including a plurality of organic light-emitting devices and a polarizing member (polarizing plate) 341 on a light extraction surface side. In addition, an opening (contact hole) is formed between the adjacent organic light-emitting devices, that is, outside a light-emitting region, in order to connect a first electrode (reflective electrode) 300 of the organic light-emitting device and a TFT 200 for driving the organic light-emitting device to each other. On the opening, an insulating layer (device separation layer) 330 made of a resin is formed as a layer for covering the opening. The insulating layer 330 has another opening which is different from the above-mentioned opening (contact hole) and defines a light-emitting region. Further, because the insulating layer 330 is a light transmissive member including no black resin or pigment, the disadvantages occurring in a pixel or a periphery thereof such as stepped cut or short circuiting, which have been the problem of the conventional apparatus configuration, can be reduced. Moreover, above the insulating layer 330, a light shielding layer 340 is formed covering the opening.

Accordingly, of lights incident on the organic light-emitting apparatus from the outside, a light incident on the contact hole region enters the light shielding layer 340 formed above the insulating layer 330. When the light shielding layer 340 is a light absorbing member, the ambient light is absorbed as such thereby, so that ambient light which exits to the outside can be remarkably reduced. Furthermore, even when the light shielding layer 340 is a light reflection member, ambient light reflected by the light shielding layer 340 can be reduced in transmission by the polarizing member 341. The reason is that because the reflection on the light shielding layer 340 corresponds to an odd number of reflections, the exit of light can be suppressed.

Accordingly, the insulating layer 330 is preferably leveled above the opening, but may not be leveled. When the insulating layer 330 is leveled, the light shielding layer 340 formed above the insulating layer 330 is formed so as to have flatness, so that the reflection on the light shielding layer 340 becomes an odd number of reflections. Alternatively, even when the insulating layer 330 is not leveled, it is sufficient that the light shielding layer 340 formed thereabove is leveled, or the light shielding layer 340 is a light absorbing member.

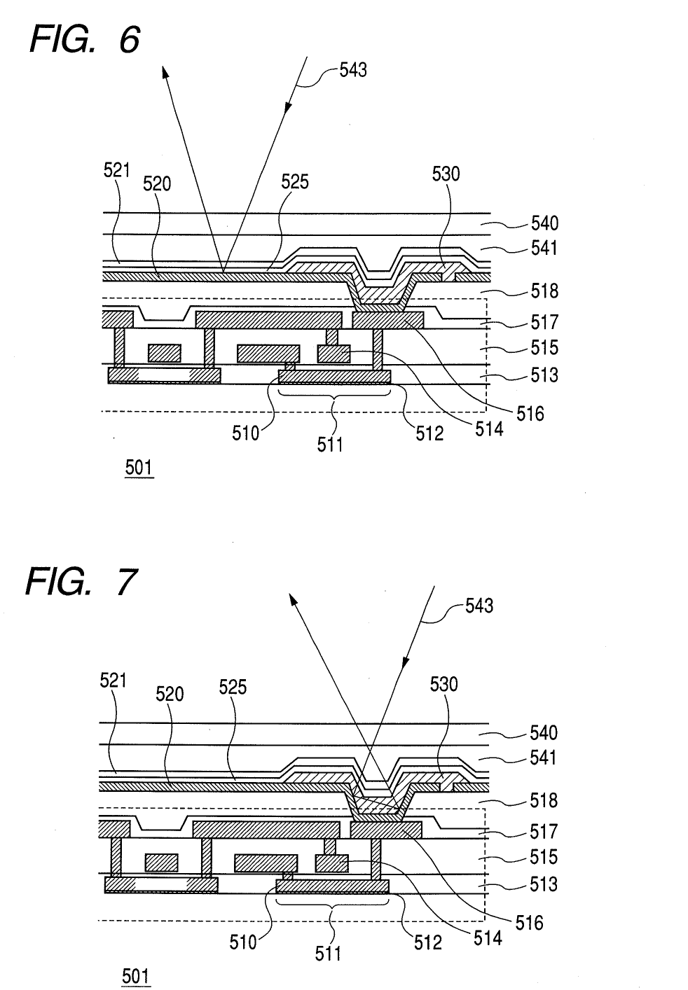

Further, the light reflection in the light-emitting region also corresponds to an odd number of reflections such as illustrated in FIG. 6. Therefore, the provision of the polarizing plate 341 on the light extraction side can suppress exit of the reflected light to the outside, and an organic light-emitting apparatus can be provided which has a high contrast in a light environment.

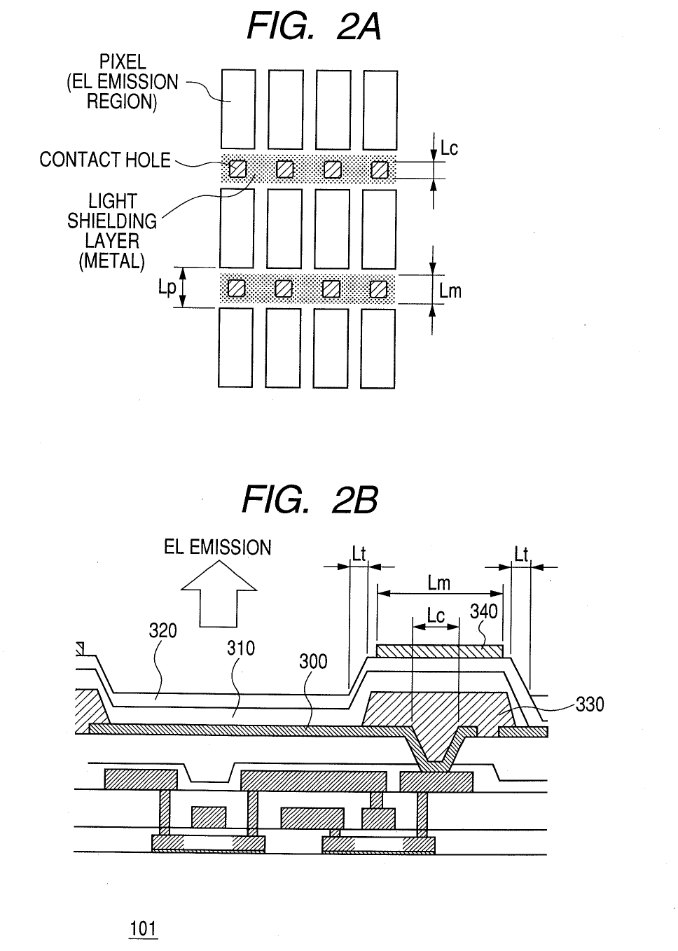

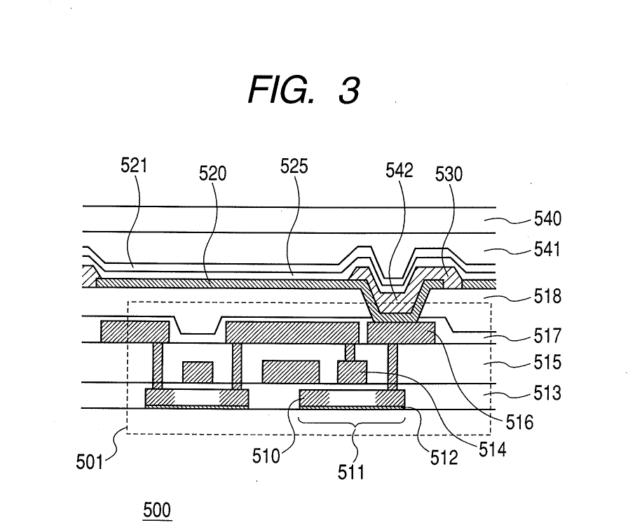

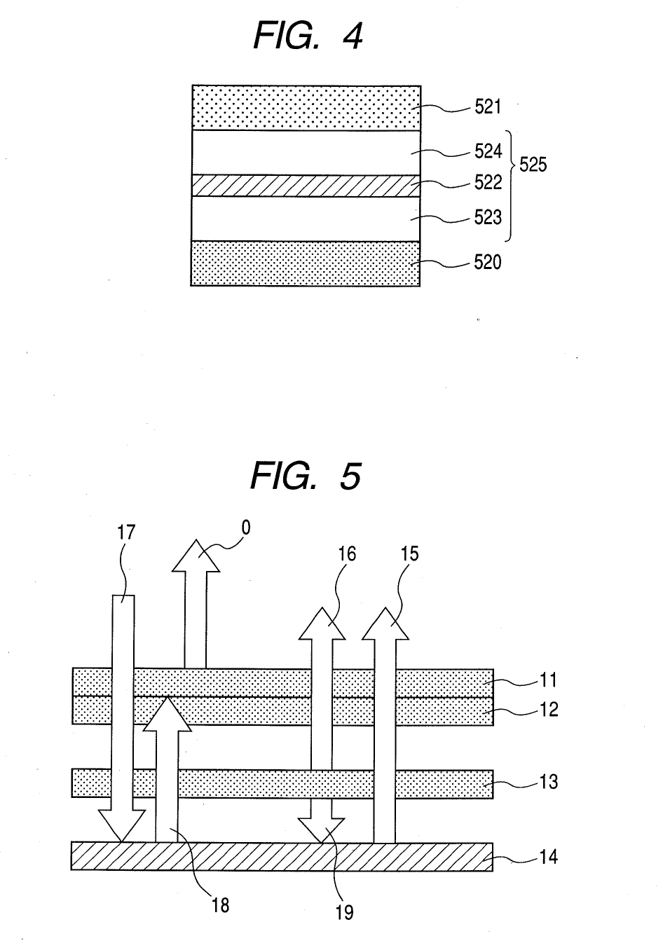

Incidentally, as illustrated in FIGS. 2A and 2B, it is desirable that the width Lm of the light shielding layer 340 is lager than the width Lc of the opening but is smaller than the spacing Lp between organic light-emitting devices (pixels) which are adjacent to each other with the opening therebetween. Thereby, of lights incident on the organic light-emitting apparatus from the outside, a light incident on the opening can more surely be reflected by the light shielding layer 340.

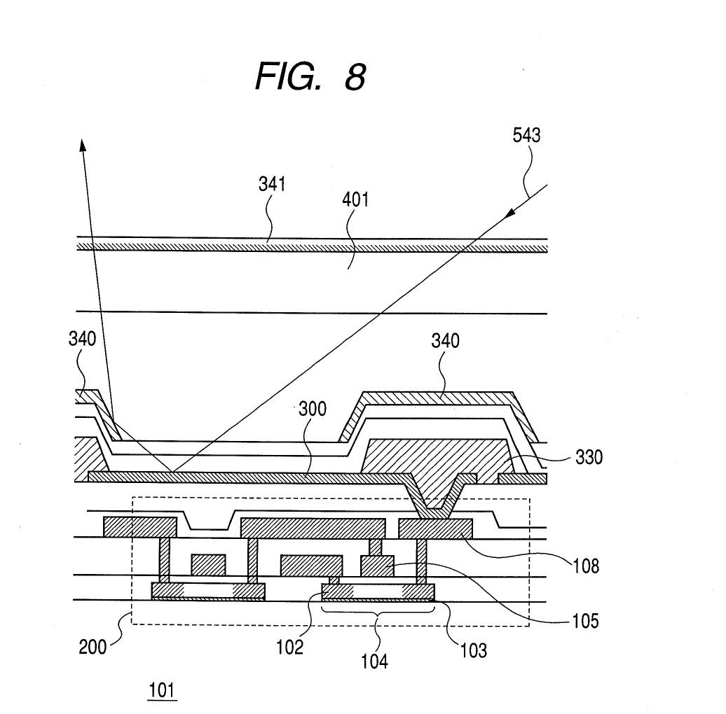

In addition, the light shielding layer 340 is preferably formed in a region excluding a tapered portion Lt of the insulating layer 330 existing around the light-emitting region. In other words, it is desirable that the light shielding layer 340 is not formed on the tapered portion Lt. When the light shielding layer 340 is disposed on the tapered portion Lt of the insulating layer 330, there are cases where as shown in an example illustrated in FIG. 8, incident light 543 is reflected an even number of times by elements including the light shielding layer 340 disposed on the tapered portion Lt of the insulating layer 330 and passes through the polarizing plate 341 to exit to the outside of the apparatus.

A specific configuration of the above described organic light-emitting apparatus will now be described according to production steps.

A TFT 200 for driving an organic light-emitting device is formed on a substrate 101. The substrate 101 may be either transparent or non-transparent, and may also be an insulating substrate made of a synthetic resin or the like, or an electroconductive substrate or a semiconductor substrate having an insulating film such as a silicon oxide (SiOₓ) film or a silicon nitride (SiNₓ) film formed on a surface thereof. Poly-Si 104 as an active layer made of poly-silicon which is a semiconductor layer of the TFT 200 need not necessarily be poly-silicon, and amorphous silicon or microcrystalline silicon may be used instead thereof.

The TFT 200 is covered with an inorganic insulating layer 109 made of silicon nitride, and is further covered with an organic planarizing layer 110 made of an acrylic resin so as to level the surface. The inorganic insulating layer 109 may be an inorganic insulating layer made of silicon oxynitride or silicon oxide. The organic planarizing layer 110 may also be made of a polyimide resin, a norbornene resin or a fluororesin.

At the light-emitting region, a first electrode (reflective electrode) 300 is formed as an anode. The first electrode 300 is patterned for each of the organic light-emitting devices, and the first electrode 300 and the drain electrode 108 of the TFT 200 are electrically connected to each other through the opening which is formed in the inorganic insulating layer 109 and the organic planarizing layer 110.

Incidentally, the first electrode 300 is formed of chromium in the present embodiment, but also may be a silver film or a silver film containing an additive; an aluminum film or an aluminum film containing an additive; or an aluminum alloy film.

Further, on the first electrode 300, an electrode having a high work function such as a transparent conductive oxide layer, for example, ITO (indium tin oxide) or IZO (indium zinc oxide) may be further formed, in order to improve injection of carriers into the organic compound layer 310.

Furthermore, the first electrode 300 and the drain electrode 108 of the TFT 200 may be directly connected to each other, but may be connected through a metal such as an aluminum film or a conductive oxide film such as ITO.

In order to cover a periphery of the first electrode 300 and to cover the opening formed between adjacent pixels, an insulating layer (device separation layer) 330 which is a resin film is formed as a layer for covering the opening. As the material of the insulating layer 330, there may be used an acrylic resin, a polyimide resin or a novolak resin.

On the first electrode 300 which is exposed through the opening of the insulating layer 330, an organic compound layer 310 and further a second electrode (transparent electrode) 320, which becomes a cathode, are formed. The organic compound layer 310 is composed of three layers, for instance, a hole-transporting layer, a light-emitting layer and an electron-transporting layer. However, the organic compound layer 310 may be composed of only a light-emitting layer, or a plurality of layers such as two or four layers.

As the material of the hole-transporting layer, FL03 which has an electron-donating property is used, for instance, but another material may be used.

The light-emitting layer is formed for each emission color, and is separately coated by use of a metal mask. For instance, CBP doped with Ir(piq)₃ is used for a red-light-emitting layer, Alq₃ doped with coumarin is used for a green-light-emitting layer, and B-Alq₃ doped with perylene is used for a blue-light-emitting layer, but another material may be used as well.

As the material of the electron-transporting layer, bathophenanthroline which has an electron-accepting is used, for instance, but another material may be used as well.

Examples of the materials used for the hole-transporting layer, the light-emitting layer and an electron injection layer which can constitute the above described organic compound layer 310 are enumerated below.

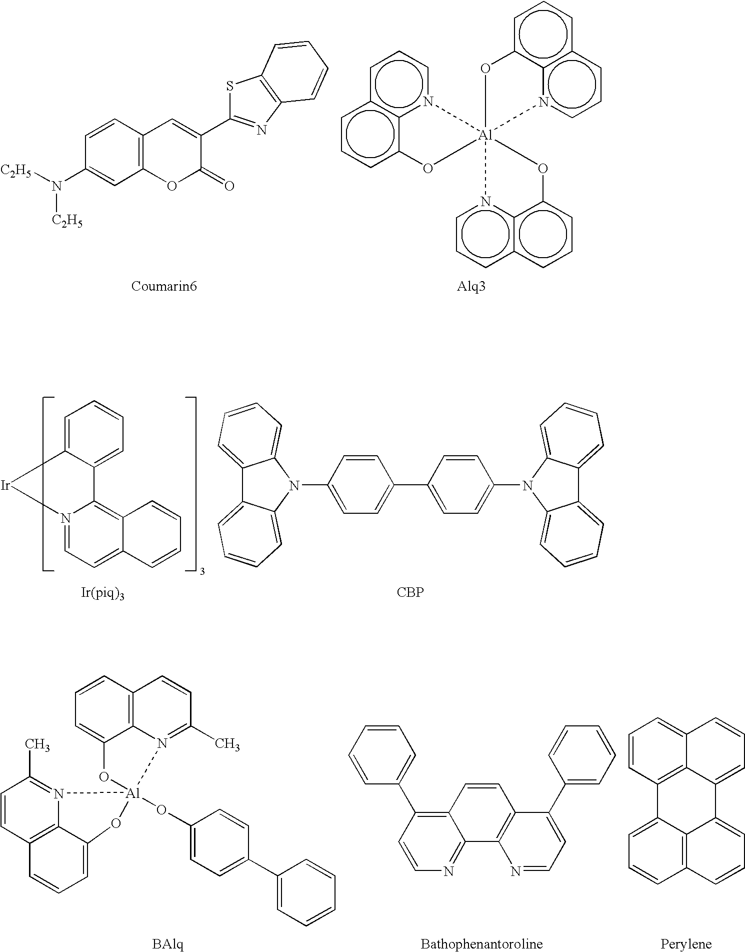

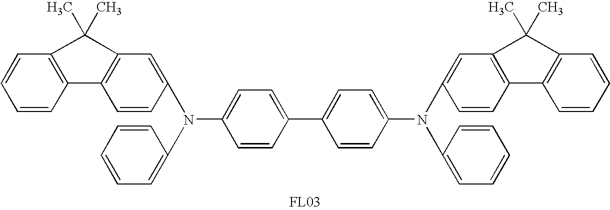

The second electrode 320 is a light transmissive electrode. In the present embodiment, IZO is used. However, a transparent electrode using a transparent conductive oxide layer such as ITO, or a translucent electrode using a translucent metal layer such as silver, aluminum or gold may also be used.

The light shielding layer 340 is formed above the insulating layer 330, specifically on the second electrode 320 formed on the insulating layer 330 in FIG. 1. As the material of the light shielding layer 340, aluminum is used, but another metal, or aluminum or another metal added with an additive may also be used. The light shielding layer 340 is formed in a film by a vapor deposition process, and is separately coated by using a metal mask, but may be formed in a film by a CVD process or may be separately coated by using a photolithographic process or the like.

At this time, as described above, it is desirable that the width Lm of the light shielding layer 340 is larger than the opening width Lc of the contact hole but is smaller than the spacing Lp between pixels which are adjacent to each other. In addition, it is also desirable that the light shielding layer 340 is formed in a region excluding the tapered portion Lt of the insulating layer 330.

The light shielding layer 340 is formed on the second electrode 320, but may be formed on the insulating layer 330. In short, it is sufficient that the light shielding layer 340 is formed so as to cover the opening of the planarizing layer.

The light shielding layer 340 illustrated in FIG. 2 is formed continuously extending over a plurality of openings, but may be independently formed so as to correspond to one of the openings. Alternatively, a light shielding layer 340 formed continuously extending over a plurality of openings (for instance, three, six or the like) may be provided in plurality.

Incidentally, when the second electrode 320 is a common electrode formed continuously extending over a plurality of pixels, and further when the light shielding layer 340 is an electroconductive member, by forming the light shielding layer 340 so as to be in contact with the second electrode, the light shielding layer 340 can serve as an auxiliary line for ensuring electrical conduction of the second electrode 320. In this case, it is desirable that the light shielding layer 340 is formed continuously extending over a plurality of openings of the planarizing layer.

In order to prevent degradation due to moisture from the outside, a sealing glass substrate 401 is bonded to the substrate 101 by using an UV curable epoxy resin in a nitrogen atmosphere with a dewpoint of −60° C. or less, and dry nitrogen 402 is filled inside the sealing glass substrate 401. At this time, it is desirable that a moisture absorbent layer such as strontium oxide and calcium oxide is formed on the organic light-emitting device side of the sealing glass substrate 401. In addition, although in this embodiment the seal is performed by the sealing glass substrate 401, the seal may be attained by an inorganic insulating layer made of silicon nitride, silicon oxynitride, silicon oxide or the like.

To the sealing glass substrate 401, a polarizing member (polarizing plate) 341 composed of a phase difference compensation film and a polarizing film is bonded by using an adhesive. The phase difference compensation film and the polarizing film may be bonded by using an adhesive.

The organic light-emitting apparatus according to the present invention can be applied to a display unit of various electrical equipments, such as a display unit of a television receiver, a display unit of a computer, a display unit of a mobile phone, a display unit of a personal digital assistant (PDA), a display unit of an audio player, a display unit of a car navigation system, an electronic view finder of an imaging device and a lighting equipment.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions. This application claims the benefit of Japanese Patent Application Nos. 2006-343772, filed Dec. 21, 2006, and 2007-301429, filed Nov. 21, 2007 which are hereby incorporated by reference herein in their entirety.

What is claimed is:

1. An organic light-emitting apparatus comprising:
a substrate;
a plurality of thin-film transistors formed on the substrate;
a planarizing layer formed on the plurality of thin-film transistors;
a plurality of organic light-emitting devices formed on the planarizing layer, each of which has formed sequentially, on the planarizing layer, a first electrode which is patterned for the organic light-emitting device concerned and is electrically connected to the thin-film transistor through an opening formed in the planarizing layer; an organic compound layer; and a second electrode which is a light transmissive electrode;
an insulating layer which is a light transmissive member, covers the opening in the planarizing layer and a region between the adjacent first electrodes, and has an opening defining a light-emitting portion of the organic light-emitting device;
a light shielding layer which is formed on the insulating layer and covers the opening in the planarizing layer; and
a circularly polarizing member which is disposed on the plurality of organic light-emitting devices and the light shielding layer.

2. The organic light-emitting apparatus according to claim 1, wherein the second electrode is formed continuously extending over the plurality of organic light-emitting devices, and wherein the light shielding layer is an electroconductive member and is an auxiliary line which is in contact with the second electrode, for ensuring electrical conduction of the second electrode.

3. The organic light-emitting apparatus according to claim 2, wherein the light shielding layer is formed continuously extending over the openings in the planarizing layer.

4. The organic light-emitting apparatus according to claim 2, wherein the light shielding layer is not formed at a tapered portion formed of the insulating layer at a periphery of the organic light-emitting device.

5. The organic light-emitting apparatus according to claim 1, wherein the light shielding layer is formed continuously extending over the openings in the planarizing layer and has a width which is larger than a size of the opening in the planarizing layer but is smaller than a spacing between adjacent ones of the organic light-emitting devices.
